(19) United States
(12) Patent Application Publication
(10) Pub. No.: US 2011/0203106 A1
(43) Pub. Date: Aug. 25, 2011

(54) ELECTRONIC COMPONENT MOUNTING SYSTEM AND ELECTRONIC COMPONENT MOUNTING MACHINE

(75) Inventors: Yuji Tanaka, Fukuoka (JP); Yuji Ogata, Fukuoka (JP); Toshiyuki Murakami, Saga (JP); Hiroto Miyazaki, Fukuoka (JP); Youichi Tanaka, Fukuoka (JP)

(73) Assignee: PANASONIC CORPORATION, Osaka (JP)

(21) Appl. No.: 12/675,871

(22) PCT Filed: Aug. 12, 2008
(86) PCT No.: PCT/JP2008/002203

§ 371 Date: Mar. 1, 2010

(30) Foreign Application Priority Data
Sep. 25, 2007 (JP) P2007-247036

(51) Int. Cl. H05K 13/04; B23P 21/00

(52) U.S. Cl. 29/720; 29/739

(57) ABSTRACT

An object of the invention is to provide an electronic component mounting system formed by interlinking a plurality of electronic component mounting machines in series for enabling a machine operator to be prevented from mistaking the machine to which an operation section or a signal tower belongs for another.

In each of machines M1 to M5 making up an electronic component mounting system formed by interlinking a plurality of machines in series, an operation section 4 placed to one direction side from a center in the board conveying direction of the machine on a machine side face MS is placed in an attitude in which the normal direction of an operation face 4a is inclined toward the center line CL side. A signal tower 22 placed to one direction side from a center line CL on the top face of the machine is placed in an attitude in which at least one portion is inclined only at an angle β toward the center line CL side. Accordingly, the machine operator can be effectively prevented from mistaking the machine to which the operation section 4 or the signal tower 22 belongs for an adjacent machine.

### TECHNICAL FIELD

This invention relates to an electronic component mounting system formed by interlinking a plurality of electronic component mounting machines for mounting electronic components on a board to manufacture a mounting board and the electronic component mounting machine.

### BACKGROUND ART

An electronic component mounting system for mounting electronic components on a board to manufacture a mounting board is formed by interlinking a plurality of electronic component mounting machines such as a screen printer, an electronic component mount machine, and an inspection machine. Each of the electronic component mounting machines is provided with a display panel for giving various operation commands to a machine operator and a signal tower for providing various notifications for the machine operator with a signal light as well as an operation panel for the machine operator to perform operation input (refer to Patent Document 1).

In recent years, it has become a general practice to produce small batches of a variety of products in the manufacturing mode of electronic devices, and a mode in which a large number of small-size facilities are interlinked to form an electronic component mounting system appears for the purposes of enhancement of area productivity and flexibility in the facility configuration (refer to Patent Document 2). In a related art example shown in Patent Document 2, a plurality of slim unit devices each having a dimension of about several hundreds of mm in a board conveying direction are detachably interlinked to make up a mount line of electronic components.

Patent document 1: Japanese Patent No. 3894208
Patent document 2: Japanese Patent Laid-Open No. 2004-104075

### DISCLOSURE OF THE INVENTION

### Problems to be Solved by the Invention

However, when the machine operator operates each unit device individually in the facilities of the configuration of interlinking a plurality of small-size, slim unit devices as described above, the following problem is caused to occur by consecutive arrangement of a large number of devices of the same configuration: When the machine operator operates each device individually, he or she needs to determine the device to be operated and further determine the operation panel corresponding to the device and then perform necessary operation input.

However, if the devices of the same configuration are arranged densely at short joint pitches as described above, operation sections each provided with a display panel and an operation panel are also arranged with equal spacing at the same pitches and thus a situation in which the machine operator accessing the unit device to be operated mistakes the essential operation section to be operated for the operation section belonging to the adjacent device often occurs. Such a mistake easily occurs particularly in a machine of the type wherein mount mechanisms are placed symmetrically on both left and right sides of a board conveying path.

That is, to operate one mount mechanism and to operate an opposite mount mechanism, the left-right positional relationship with respect to the device center of the operation section viewed from the machine operator becomes opposite and thus an operation mistake caused by such a mistake mentioned above tends to often occur in work wherein operations on both left and right sides of the same mount line are mixed. Such a mistake also occurs likewise for a signal tower attached to each unit device and the machine operator may confuse the essential device to be accessed for the device positioned in which direction of the signal tower lightened for making an access request.

It is therefore an object of the invention to provide an electronic component mounting system formed by interlinking a plurality of electronic component mounting machines in series for enabling a machine operator to be prevented from mistaking the machine to which an operation section or a signal tower belongs for another.

### Means for Solving the Problems

An electronic component mounting system of the invention is an electronic component mounting system formed by interlinking a plurality of electronic component mounting machines in series for mounting an electronic component on a board to manufacture a mounting board, wherein each of the electronic component mounting machines includes a work operation mechanism that performs the work operation for mounting an electronic component, a control section that controls the work operation mechanism, and an operation section being placed at a position shifting to one direction side from a center position in a board conveying direction of the machine on a machine side face that is along the board conveying direction for a machine operator to perform operation input to the control section, and wherein an operation face to which the machine operator is opposed for operating the operation section is placed in an attitude in which a normal direction is inclined toward the center position side in a horizontal plane.

An electronic component mounting system of the invention is an electronic component mounting system formed by interlinking a plurality of electronic component mounting machines in series for mounting an electronic component on a board to manufacture a mounting board, wherein each of the electronic component mounting machines includes a work operation mechanism that performs the work operation for mounting an electronic component, a control section that controls the work operation mechanism, and a signal tower being placed at a position shifting to one direction side from a center position in a board conveying direction of the machine on a machine top face for providing predetermined notification for a machine operator with a signal light under control of the control section, and wherein the signal tower is placed in an attitude in which at least one portion of the signal tower is inclined toward the center position side in a perpendicular plane containing the board conveying direction.

An electronic component mounting machine of the invention is an electronic component mounting machine forming a part of an electronic component mounting system having a plurality of machines interlinked in series, thereby mounting an electronic component on a board to manufacture a mounting board, and includes a work operation mechanism that performs the work operation for mounting an electronic component; a control section that controls the work operation mechanism; and an operation section being placed at a position shifting to one direction side from a center position in a board conveying direction of the machine on a machine side face that is along the board conveying direction for a machine operator to perform operation input to the control section, wherein an operation face to which the machine operator is opposed for operating the operation section is placed in an attitude in which a normal direction is inclined toward the center position side in a horizontal plane.

An electronic component mounting machine of the invention is an electronic component mounting machine forming a part of an electronic component mounting system having a plurality of machines interlinked in series, thereby mounting an electronic component on a board to manufacture a mounting board, and includes a work operation mechanism that performs the work operation for mounting an electronic component; a control section that controls the work operation mechanism; and a signal tower being placed at a position shifting to one direction side from a center position in a board conveying direction of the machine on a machine top face for providing predetermined notification for a machine operator with a signal light under control of the control section, wherein the signal tower is placed in an attitude in which at least one portion of the signal tower is inclined toward the center position side in a perpendicular plane containing the board conveying direction.

### ADVANTAGES OF THE INVENTION

According to the invention, in the electronic component mounting machine forming a part of the electronic component mounting system having a plurality of machines interlinked in series, the operation section placed at a position shifting to one direction side from the center position in the board conveying direction of the machine on the machine side face is placed in the attitude in which the normal direction of the operation face is inclined toward the center position side, whereby the machine operator can be effectively prevented from mistaking the machine to which the operation section belongs for another.

In the electronic component mounting machine, the signal tower placed to one direction side from the center position in the board conveying direction of the machine on the top face of the machine is placed in the attitude in which at least one portion of the signal tower is inclined toward the center position side, whereby the machine operator can be effectively prevented from mistaking the machine to which the signal tower belongs for another.

### BRIEF DESCRIPTION OF THE DRAWINGS

FIG. 1 is a perspective view of an electronic component mounting system of an embodiment of the invention.

FIG. 2 is a plan view of each of electronic component mounting machine making up the electronic component mounting system of the embodiment of the invention.

FIG. 3 is a fragmentary plan view and a side view of each of the electronic component mounting machine making up the electronic component mounting system of the embodiment of the invention.

FIG. 4 is a block diagram to show the configuration of a control system of the electronic component mounting system of the embodiment of the invention.

FIG. 5 is a fragmentary perspective view of each of the electronic component mounting machines making up the electronic component mounting system of the embodiment of the invention.

### DESCRIPTION OF REFERENCE NUMERALS

1 Electronic component mounting system

4 Operation section

4a Operation face

5 Component supply section

6 Tape feeder

7 Tape reel

9 Board

11 Y-axis move table

12 X-axis move table

13 Mount head

22 Signal tower

M1-M5 Electronic component mounting machine

M* Operation target machine

M (R) Adjacent machine

MS Machine side face

### BEST MODE FOR CARRYING OUT THE INVENTION

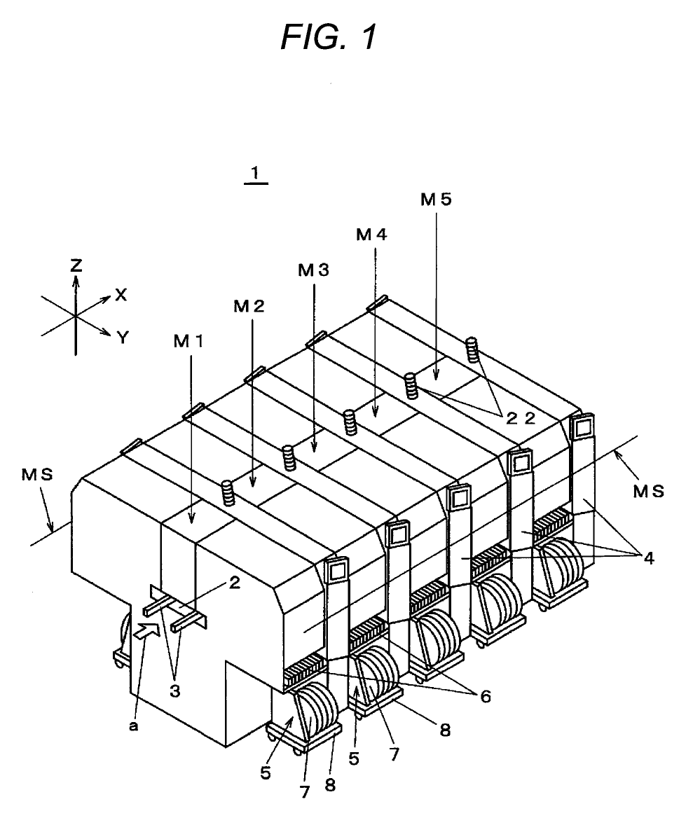

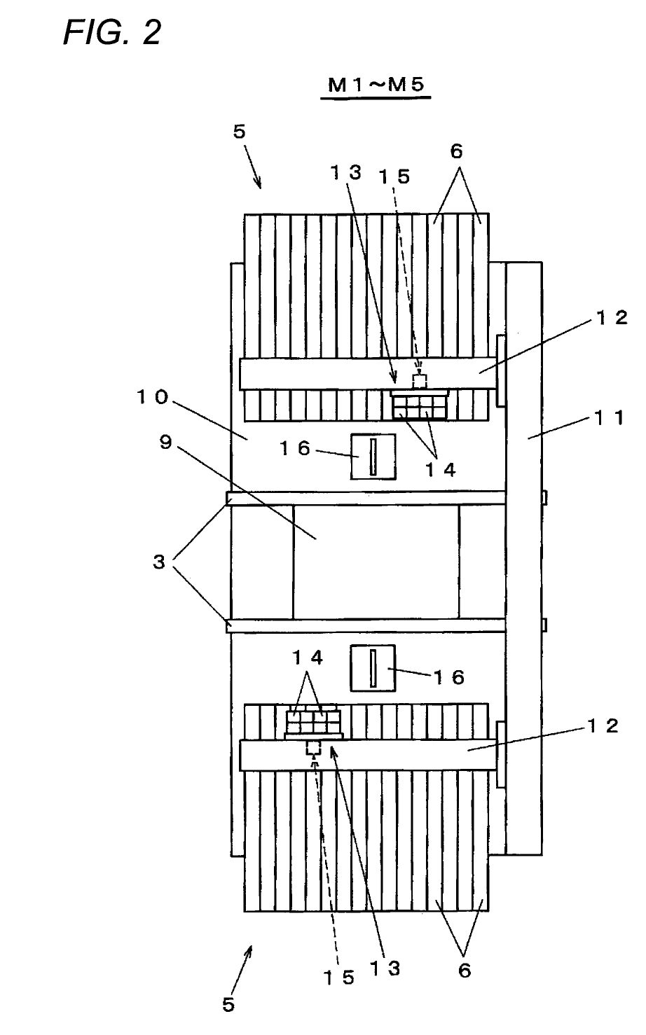

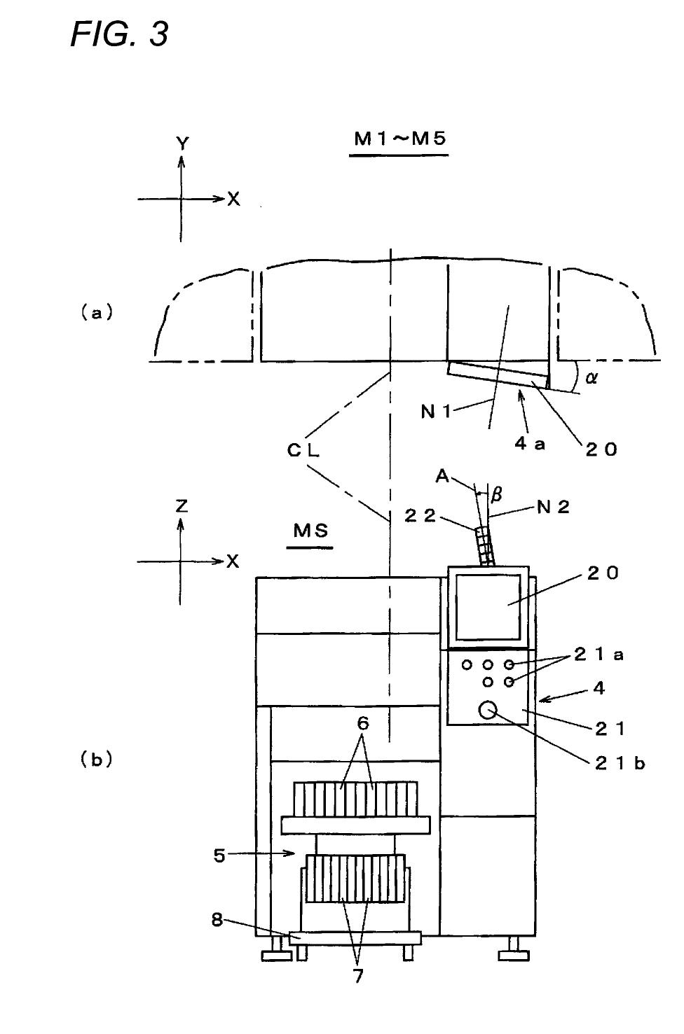

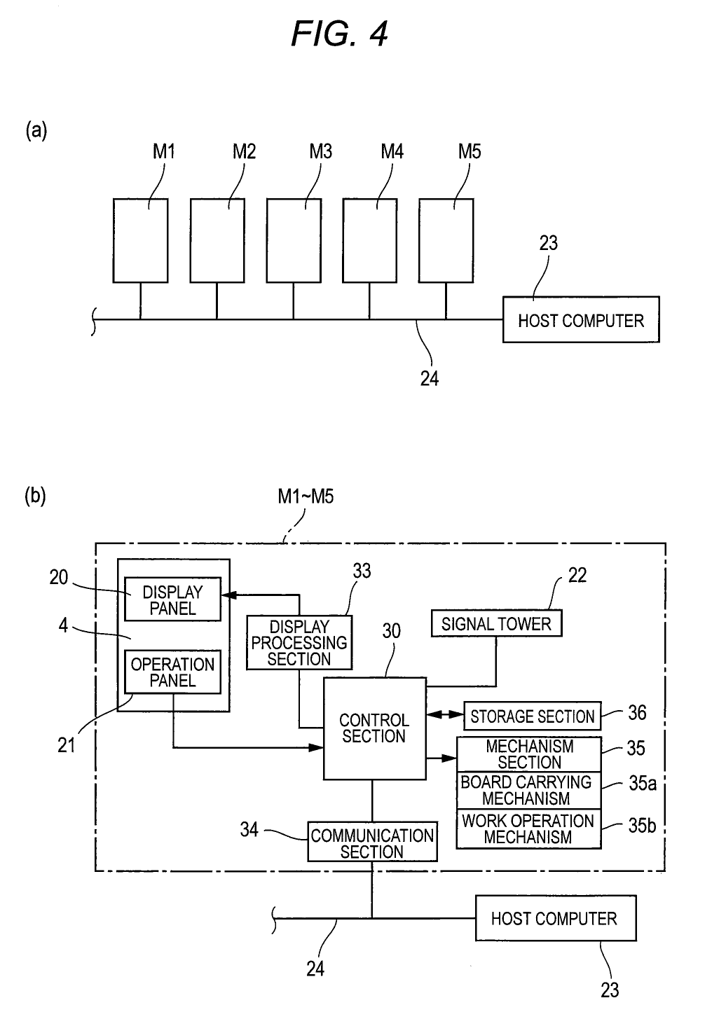

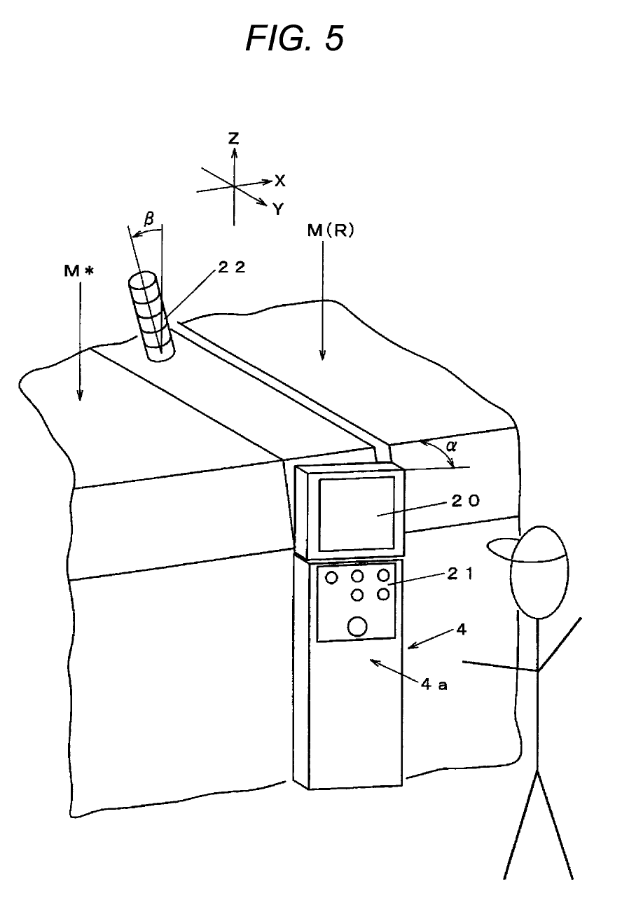

Next, an embodiment of the invention will be discussed with reference to the accompanying drawings. FIG. 1 is a perspective view of an electronic component mounting system of an embodiment of the invention, FIG. 2 is a plan view of each of electronic component mounting machines making up the electronic component mounting system of the embodiment of the invention, FIG. 3 is a fragmentary plan view and a side view of each of the electronic component mounting machines making up the electronic component mounting system of the embodiment of the invention, FIG. 4 is a block diagram to show the configuration of a control system of the electronic component mounting system of the embodiment of the invention, and FIG. 5 is a fragmentary perspective view of each of the electronic component mounting machines making up the electronic component mounting system of the embodiment of the invention.

First, the configuration of an electronic component mounting system 1 will be discussed with reference to FIG. 1. The electronic component mounting system 1 is formed by interlinking electronic component installing devices as a plurality of electronic component mounting machines (which will be hereinafter referred simply as “machine”) M1, M2, M3, M4, and M5 in series and has a function of mounting electronic components on a board to manufacture a mounting board. A board on which electronic components are to be mounted, supplied from upstream (arrow a) is passed to a board conveying mechanism 3 through a conveying opening 2 provided in the machine M1 positioned in the uppermost stream and is conveyed in sequence in an X direction (board conveying direction) in the electronic component mounting system 1. The conveyed-in board is subjected to component mounting work by each machine and the board after subjected to the component mounting work is conveyed out to a further downstream machine.

In the electronic component mounting system 1, the machines M1 to M5 are placed in a mode in which machine side faces MS parallel with each other along the board conveying direction are made adjacent to each other in the same perpendicular plane. An operation section 4 for a machine operator to operate the machine and a component supply section 5 for supplying an electronic component to the machine are disposed on each of the machine side faces MS. A carriage 8 holding in parallel a plurality of tape feeders 6 and a plurality of tape reels 7 for supplying electronic components is attached to the component supply section 5. The tape feeder 6 supplies an electronic component held on carrier tape to a component mounting mechanism described later, and the tape reel 7 winds and houses eth carrier tape supplied to the tape feeder 6.

Next, the structure of each of the machines M1 to M5 will be discussed with reference to FIG. 2. In FIG. 2, the board conveying mechanism 3 is disposed in the X direction on a base 10. A board 9 supplied from an upstream machine and to be subjected to the mounting work operation by the machine is conveyed by the board conveying mechanism 3 and is positioned and is held at a component mounting work position. The component supply section 5 is provided on both sides of the board conveying mechanism 3, and a plurality of tape feeders 6 are attached to each of the component supply sections 5. A Y-axis move table 11 including a linear drive mechanism is disposed horizontally in a Y direction in one end part in the X direction of the base 10, and X-axis move tables 12 including a linear drive mechanism are interlinked to the Y-axis move table 11. A mount head 13 is attached to each of the X-axis move tables 12 movably in the X direction.

The mount head 13 is a multi-type head including a plurality of (here, eight) unit mount heads 14, and each of the unit mount heads 14 absorbs and holds an electronic component by an adsorption nozzle (not shown) attached to the lower end part. The Y-axis move table 11 and the X-axis move tables 12 make up a head move mechanism and this head move mechanism is driven, whereby the mount head 13 moves in the X direction and the Y direction, whereby each of the unit mount heads 14 takes out an electronic component from the tape feeder 6 of the component supply section 5 and moves the electronic component to the board 9 positioned at the board conveying mechanism 3 and mounts the electronic component on the board.

Therefore, the Y-axis move table 11, the first X-axis move table 12, and the mount head 13 become a component mounting mechanism for moving the mount head 13 with an electronic component held thereon by the head move mechanism, thereby moving the electronic component to the board 9 and mounting the electronic component thereon (namely, a work operation mechanism that performs the work operation for mounting electronic components in the electronic component mounting machine as the electronic component mounting machine). A component recognition device 16 is disposed between the component supply section 5 and the board conveying mechanism 3; when the mount head 13 taking out an electronic component from the component supply section 5 moves above the component recognition device 16, the component recognition device 16 picks up an image of the electronic component held on the mount head 13 and recognizes the electronic component.

A board recognition camera 15 positioned on the lower face side of the X-axis move table 12 and moving in one piece is attached to the mount head 13. The mount head 13 is moved, whereby the board recognition camera 15 moves to a position above the board 9 positioned at the board conveying mechanism 3 and picks up an image of the board 9 and recognizes the board. In the electronic component mounting operation on the board 9 by the mount head 13, the electronic component recognition result of the component recognition device 16 and the board recognition result of the board recognition camera 15 are added for making an mounting position correction.

Next, the arrangement of the sections on the machine side face MS of each of the machines M1 to M5 will be discussed with reference to FIG. 3. As shown in FIG. 3 (b), the operation section 4 is disposed in a longitudinal attitude at a position on one side of the component supply section 5. Here, the operation section 4 on the machine side face MS is placed to a downstream position in the board conveying direction from a center line CL in the X direction of the machine. That is, the operation section 4 is placed to a position on one direction side (downstream in the conveying direction) from the center position (center line CL) with respect to the board conveying direction of the machine (X direction).

Further, as shown in FIG. 4 (a), the operation section 4 has an operation face 4a operated by the machine operator opposed thereto; the operation face 4a is not placed in parallel in the X direction and is inclined only at a given angle (predetermined angle α) with respect to the X-axis. The predetermined angle α is set in the range of 5 to 30° and usually an angle of about 10° is selected. The operation face 4a operated by the machine operator opposed thereto in the operation section 4 is placed with a normal N1 orthogonal to the operation face 4a inclined to the center line CL side. That is, the operation section 4 is placed in an attitude with the normal direction of the operation face 4a inclined toward the center position side in a horizontal plane.

A display panel 20 made of a display of a liquid crystal panel, etc., is placed in an upper part of the operation section 4 and displays various screens including an operation command screen for the machine operator. An operation panel 21 for the machine operator to perform operation input to a control section (see a control section 30 shown in FIG. 4) is provided below the display panel 20, and operation buttons 21a for performing various operation inputs, an emergency stop button 21b, and the like are placed on the operation panel 21.

In the component supply section 5, when the machine operator exchanges the carriage 8 or maintains the tape feeders 6, the machine operator operates the tape feeders 6 and the operation button 21a in accordance with a command of an operation command screen displayed on the display panel 20. A signal tower 22 is projected on a top cover provided on the machine top face of each of the machines M1 to M5 (also see FIG. 1). If component depletion, a machine operation anomaly, etc., occurs and it becomes necessary for the machine operator to take measures, the signal tower 22 provides predetermined notification for the machine operator by lighting a signal light under control of the control section (see the control section 30 shown in FIG. 4).

Here, the position and the attitude of the signal tower 22 on the machine top face of each of the machines will be discussed. As shown in FIG. 3 (b), the signal tower is placed to a downstream position in the board conveying direction from the center line CL in the X direction of the machine. That is, the operation section 4 is placed at a position shifting to one direction side (downstream in the conveying direction) from the center position (center line CL) with respect to the board conveying direction (X direction) of the machine. The direction in which the signal tower 22 projects upward from the machine top face is not a perpendicular upward direction, and an axis A of the signal tower 22 is inclined only at a predetermined acute angle β to the center line CL side from a perpendicular line N2 in a perpendicular plane containing the X-axis. The angle β is also set in the range of 5 to 30°.

Here, an example wherein the signal tower 22 shaped like a linear pipe is placed as it is inclined as a whole is shown, but the signal tower may use a shape bent at a midpoint and only the bend part may be inclined, in which case the signal tower 22 is placed in an attitude with only one portion inclined. That is, in the embodiment, at least one portion of the signal tower 22 is placed in an attitude inclined toward the center position side of the machine in the perpendicular plane containing the board conveying direction.

Next, the configuration of a control system of the electronic component mounting system 1 will be discussed with reference to FIG. 4. As shown in FIG. 4 (a), the machines M1 to M5 are connected to a host computer 23 through a LAN system 24, and the host computer 23 controls the whole operation of the machines M1 to M5. FIG. 4 (b) shows the configuration of a control system that each of the machines M1 to M5 has. The configuration and the function of the individual control system will be discussed below:

As shown in FIG. 4 (b), each of the machines M1 to M5 includes a control section 30 that performs a control function, a display processing section 33, a communication section 34, and a storage section 36. The control section 30 is a CPU and controls the sections making up the machine. The display processing section 33 performs processing of displaying image data on the display panel 20 provided in the operation section 4 under control of the control section 30. The control section 30 controls the operation of a board conveying mechanism 35a and a work operation mechanism 35b making up a mechanism section 35 and also controls lighting of the signal tower 22, thereby providing predetermined notification for the machine operator with the signal light.

An operation signal input by the machine operator operating the operation panel 21 is input to the control section 30. The communication section 34 is connected to the control section 30 and transfers a signal to and from the control section of any other machine and the host computer 23 through the LAN system 24. The storage section 36 stores an operation program and mount data for causing the mechanism section 35 to perform work operation of board conveying operation, component mounting operation, etc.

Next, the meaning of adopting the placement attitude of the signal tower 22 and the placement attitude of the operation section 4 as shown in FIG. 3 will be discussed with reference to FIG. 5 from the viewpoint of preventing a mistake of the machine operator when operating each machine. If operation for a specific machine becomes necessary while the electronic component mounting system 1 is operating, for example, if the signal tower 22 provides notification of component depletion, a machine operation anomaly, etc., the machine operator accesses the machine with component depletion, an anomaly, etc., reported, and performs necessary work of operating the operation button 21a of the operation panel 21 or the like.

In the facilities of the configuration wherein a plurality of small-size, slim unit devices are interlinked, such as the electronic component mounting system 1 as shown in FIG. 1, the devices of the same configuration are arranged densely at short joint pitches as described above and thus the machine operator may confuse the essential device to be accessed for the device positioned in which direction of the signal tower lightened for making an access request. Even if the embodiment of the invention applies to the facility of the configuration, the electronic component mounting system 1 shown in the embodiment enables the machine operator to easily determine the machine to which the signal tower 22 belongs (operation target machine M*).

That is, as shown in FIG. 5, the signal tower 22 is placed in the attitude in which at least one portion is inclined only at the predetermined angle β toward the center position side of the machine, so that the machine operator accessing the machine according to the notification provided by the signal tower 22 can visually recognize the direction of the inclination, thereby reliably determining the machine to which the signal tower 22 belongs (operation target machine M*). Therefore, a situation in which the machine operator mistakes the essential operation target machine M* for the adjacent machine M (R) easy to erroneously recognize does not occur.

In the facility of the configuration as described above, the operation sections 4 are also arranged with equal spacing at the same pitches and thus a situation in which the machine operator accessing the unit device to be operated mistakes the essential operation section 4 to be operated for the operation section 4 belonging to the adjacent device M (R) also often occurs. Such a mistake easily occurs particularly in a machine of the type wherein mount mechanisms are placed symmetrically on both left and right sides of a board conveying path. In such a case, the electronic component mounting system 1 shown in the embodiment also enables the machine operator to easily determine the machine to which the operation section 4 belongs (operation target machine M*).

That is, as shown in FIG. 5, the operation section 4 is placed in the attitude in which the operation face 4a is inclined at the predetermined angle α with respect to the X-axis and the normal direction of the operation face 4a is inclined toward the center position side of the operation target machine M* in the horizontal plane, so that the machine operator accessing the machine according to the notification provided by the signal tower 22 can visually recognize the direction of the inclination, thereby reliably determining the machine to which the operation section 4 belongs (the operation target machine M*). Therefore, a situation in which the machine operator mistakes the essential operation target machine M* for the adjacent machine M (R) easy to erroneously recognize does not occur.

Thus, in each of the electronic component mounting machine making up the electronic component mounting system 1, the normal direction of the operation face 4a of the operation section 4 is inclined toward the center position side of the machine to which the operation section belongs, whereby the machine operator can be effectively prevented from mistaking the machine to which the operation section belongs for another and further at least one portion of the signal tower 22 is inclined toward the center position side of the machine to which the signal tower 22 belongs, whereby the machine operator can be effectively prevented from mistaking the machine to which the signal tower belongs for another.

In the example shown in the embodiment, the electronic component mounting machine for performing the component mounting operation for mounting electronic components on a board has been shown as an example of the electronic component mounting machine, but the invention can also be applied to any machine for forming the electronic component mounting system, such as a solder printer for printing solder for joining an electronic component onto a board or an inspection machine for inspecting a board.

While the invention has been described in detail with reference to the specific embodiment, it will be obvious to those skilled in the art that various changes and modifications can be made without departing from the spirit and the scope of the invention.

This application is based on Japanese Patent Application No. 2007-247036 filed on Sep. 25, 2007, which is incorporated herein by reference.

### INDUSTRIAL APPLICABILITY

The electronic component mounting system and the electronic component mounting machine of the invention have the advantage that in the electronic component mounting system having a plurality of electronic component mounting machines interlinked in series, the machine operator can be effectively prevented from mistaking the machine to which the operation section or the signal tower belongs for another, and the invention is useful in an electronic component mounting system having a plurality of machines interlinked.

1. An electronic component mounting system that is formed by interlinking a plurality of electronic component mounting machines in series and that manufactures a mounting board by mounting an electronic component on a board, wherein
each of said electronic component mounting machines comprises a work operation mechanism that performs a work operation for mounting an electronic component, a control section that controls said work operation mechanism, and an operation section being placed at a position shifting to one direction side from a center position in a board conveying direction of said machine on a machine side face that is along the board conveying direction for a machine operator to perform operation input to said control section, and
an operation face to which the machine operator is opposed for operating said operation section is placed in an attitude in which a normal direction is inclined toward the center position side in a horizontal plane.

2. An electronic component mounting system formed by interlinking a plurality of electronic component mounting machines in series for mounting an electronic component on a board to manufacture a mounting board, wherein
each of said electronic component mounting machines comprises a work operation mechanism that performs a work operation for mounting an electronic component, a control section that controls said work operation mechanism, and a signal tower being placed at a position shifting to one direction side from a center position in a board conveying direction of said machine on a machine top face for providing predetermined notification for a machine operator with a signal light under control of said control section, and
said signal tower is placed in an attitude in which at least one portion of said signal tower is inclined toward the center position side in a perpendicular plane containing the board conveying direction.

3. An electronic component mounting machine forming a part of an electronic component mounting system having a plurality of machines interlinked in series, thereby mounting an electronic component on a board to manufacture a mounting board, said electronic component mounting machine comprising:
a work operation mechanism that performs a work operation for mounting an electronic component; a control section that controls said work operation mechanism; and an operation section being placed at a position shifting to one direction side from a center position in a board conveying direction of said machine on a machine side face that is along the board conveying direction for a machine operator to perform operation input to said control section, wherein
an operation face to which the machine operator is opposed for operating said operation section is placed in an attitude in which a normal direction is inclined toward the center position side in a horizontal plane.

4. An electronic component mounting machine forming a part of an electronic component mounting system having a plurality of machines interlinked in series, thereby mounting an electronic component on a board to manufacture a mounting board, said electronic component mounting machine comprising:
a work operation mechanism that performs a work operation for mounting an electronic component; a control section that controls said work operation mechanism; and a signal tower being placed at a position shifting to one direction side from a center position in a board conveying direction of said machine on a machine top face for providing predetermined notification for a machine operator with a signal light under control of said control section, wherein
said signal tower is placed in an attitude in which at least one portion of said signal tower is inclined toward the center position side in a perpendicular plane containing the board conveying direction.
